(19) United States
(12) Patent Application Publication
(10) Pub. No.: US 2025/0079795 A1
(43) Pub. Date: Mar. 6, 2025

(54) LOW-DIVERGENCE MULTI-JUNCTION VCSEL

(71) Applicant: SHENZHEN RAYSEES AI TECHNOLOGY CO., LTD., Shenzhen (CN)

(72) Inventors: Jianyang Zhao; Siva Kumar Lanka, Reno, NV (US); Yongxiang He, Sunnyvale, CA (US); Yang Wang, Hefei (CN)

(73) Assignee: SHENZHEN RAYSEES AI TECHNOLOGY CO., LTD., Shenzhen (CN)

(21) Appl. No.: 18/037,251

(22) PCT Filed: Mar. 16, 2023
(86) PCT No.: PCT/CN2023/081903

§ 371 Date: May 16, 2023

(51) Int. Cl. H01S 5/183; H01S 5/125

(52) U.S. Cl. CPC H01S 5/18311; H01S 5/125

(57) ABSTRACT

A low-divergence multi-junction VCSEL (100,200) includes a first reflector region (103,203) over a substrate (104,204), a second reflector region (102,202) over the first reflector region (103,203), active regions (101,105,106,107,201,205,206,207) between the first reflector region (103,203) and the second reflector region (102,202), an oxide aperture (115,215) and an implantation region (108,109,208,209) between the first reflector region (103,203) and the second reflector region (102,202), and a surface relief structure (112,117,212,217).

### FIELD OF INVENTION

This invention generally relates to Vertical Cavity Surface Emitting Lasers (VCSELs) and specifically to low-divergence multi-junction VCSELs.

### BACKGROUND OF THE INVENTION

Compared to edge-emitting semiconductor lasers with a horizontal Fabry-Perot resonator and cleaved facets acting as mirrors, VCSELs have a vertical cavity and emit a circular beam normal to the surface. VCSELs have many advantages over edge-emitting semiconductor lasers such as compact size, small beam spot, wavelength stability, spectral width, fast rise time, ease of fabricating two-dimensional (2-D) VCSEL array, etc.

Light detection and ranging (LIDAR) system is a critical sensing component for emerging autonomous vehicles. LIDAR systems help recognize vehicles and pedestrians on a road effectively and quickly. In VCSEL-based LIDAR systems, the detection range is often determined by the output power and beam divergence. As such, low-divergence high-power VCSELs are desirable for LIDAR applications.

Multi-junction VCSELs represent one approach to increase the output power of VCSELs. In a multi-junction VCSEL structure, the gain volume and total optical gain are increased. For example, two or more than two multi-quantum-well (MQW) active regions can be configured in series to form a multi-junction active region. As the coherent light is generated in each MQW active region, the output power can be multiplied. In addition, the slope efficiency can be improved. However, while the output power is increased, unwanted higher-order transverse modes may be excited. The higher-order transverse modes increase the beam divergence and reduce the detection range of LIDAR systems. Therefore, there exists a need for low-divergence multi-junction VCSELs.

### SUMMARY OF THE INVENTION

The present invention discloses methods and apparatus for low-divergence multi-junction VCSELs. In one aspect, a VCSEL device includes a substrate, a first reflector region over the substrate, a second reflector region over the first reflector region, active regions between the first and second reflector regions, an oxide aperture between the first and second reflector regions, an implantation region between the first and second reflector regions for electrical confinement, and a surface relief structure over the second reflector region.

In another aspect, a method for fabricating a VCSEL device includes growing a first reflector region over a substrate, growing active regions over the first reflector region, growing a second reflector region over the active regions, forming an implantation region between the first and second reflector regions for electrical confinement, forming an oxide aperture between the first and second reflector regions, and forming a surface relief structure over the second reflector region.

In another aspect, a VCSEL device includes a substrate, a first reflector region over the substrate, a second reflector region over the first reflector region, active regions between the first and second reflector regions, an oxide aperture between the first and second reflector regions, a first implantation region between the first and second reflector regions, a second implantation region between the oxide aperture and the first implantation region, and a surface relief structure over the second reflector region.

### BRIEF DESCRIPTION OF THE DRAWINGS

The subject matter, which is regarded as the invention, is particularly pointed out and distinctly claimed in the claims at the conclusion of the specification. The foregoing and other features and also the advantages of the invention will be apparent from the following detailed description taken in conjunction with the accompanying drawings.

FIG. 1 schematically illustrates a cross-sectional view of a low-divergence multi-junction VCSEL device at a certain stage during a fabrication process, according to embodiments of the present invention.

FIG. 2 schematically illustrates a cross-sectional view of the VCSEL device shown in FIG. 1 after an implantation process, according to embodiments of the present invention.

FIGS. 3-5 schematically illustrate cross-sectional views of the VCSEL device shown in FIG. 2 at certain stages during the fabrication process, according to embodiments of the present invention.

FIG. 6 schematically illustrates a cross-sectional view of the VCSEL device shown in FIG. 5 at a certain stage during the fabrication process, according to embodiments of the present invention.

FIG. 7 schematically illustrates a cross-sectional view of the VCSEL device shown in FIG. 6 after an oxidation process, according to embodiments of the present invention.

FIG. 8 schematically illustrates a cross-sectional view of the VCSEL device shown in FIG. 7 at a certain stage during the fabrication process, according to embodiments of the present invention.

FIGS. 9 and 10 schematically illustrate cross-sectional views of another low-divergence multi-junction VCSEL device at certain stages during a fabrication process, according to embodiments of the present invention.

FIG. 11 is a flow chart illustrating a schematic fabrication process, according to embodiments of the present invention.

### DETAILED DESCRIPTION

Detailed description of the present invention is provided below along with figures and embodiments, which further clarifies the objectives, technical solutions, and advantages of the present invention. Wherever possible, the same reference numbers are used throughout the drawings to refer to the same or like parts. It is noted that schematic embodiments discussed herein are merely for illustrating the invention. The present invention is not limited to the embodiments disclosed.

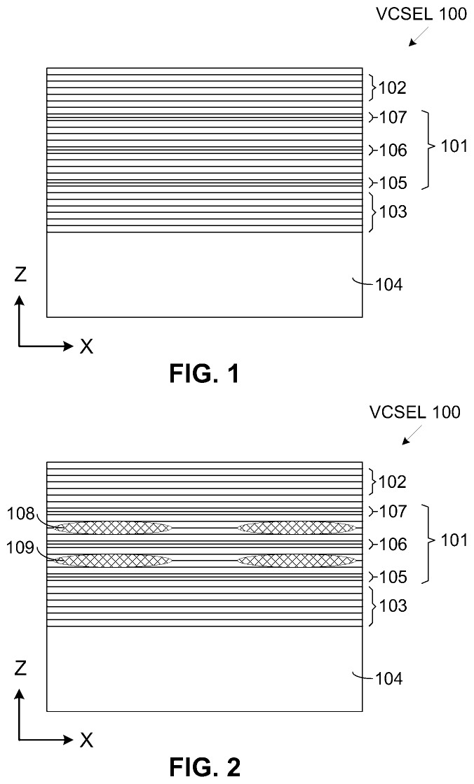

FIG. 1 shows a low-divergence multi-junction VCSEL 100 at a certain fabrication stage in a cross-sectional view according to embodiments of the present invention. Cross-sectional views in FIG. 1 and other figures of the present disclosure are in X-Z planes. As shown in FIG. 1, VCSEL 100 exemplarily includes a multi-junction active region 101, a top reflector region 102, and a bottom reflector region 103. Bottom reflector region 103, multi-junction active region 101, and top reflector region 102 are grown over a substrate 104 sequentially. Top and bottom reflector regions 102 and 103 are electrically conductive. Top reflector region 102 may contain a p-type Distributed Bragg Reflector (DBR), while bottom reflector region 103 may contain an n-type DBR. Substrate 104 may be a conductive n-type semiconductor substrate and include, for example, a Group III-V compound such as gallium arsenide (GaAs), indium phosphide (InP), or III-nitride.

Optionally, multi-junction active region 101 may contain active regions 105, 106, and 107. Active regions 105-107 each include a quantum-well configuration such as a multi-quantum-well (MQW) configuration. A tunnel junction (not shown) may be arranged between adjacent active regions (e.g., active regions 105 and 106) in some aspects. The tunnel junction connects the stacked active regions. In some embodiments, VCSEL 100 may have fewer active regions. For example, VCSEL 100 may have a similar structure with active regions 106 and 107, but may not have active region 105. In some other embodiments, VCSEL 100 may have more active regions. For example, VCSEL 100 may have a stack with additional active regions besides active regions 105-107 between the top and bottom reflector regions. The layers of the DBRs, active regions, and tunnel junctions may be grown epitaxially over a top surface of substrate 104. The epitaxial growth may be performed by molecular beam epitaxy (MBE) or metal organic chemical vapor deposition (MOCVD).

FIG. 2 schematically shows VCSEL 100 in a cross-sectional view after an ion implantation process according to embodiments of the present invention. The ion implantation process is performed to create electrical confinement, limiting lateral spreading of the injected current. Ion implantation regions 108 and 109 are formed. In some cases, regions 108 and 109 may have an annular shape or ring shape in an X-Y plane. Centers of the annular shapes are aligned in the Z direction. Region 108 is formed between active regions 106 and 107, while region 109 is formed between active regions 105 and 106.

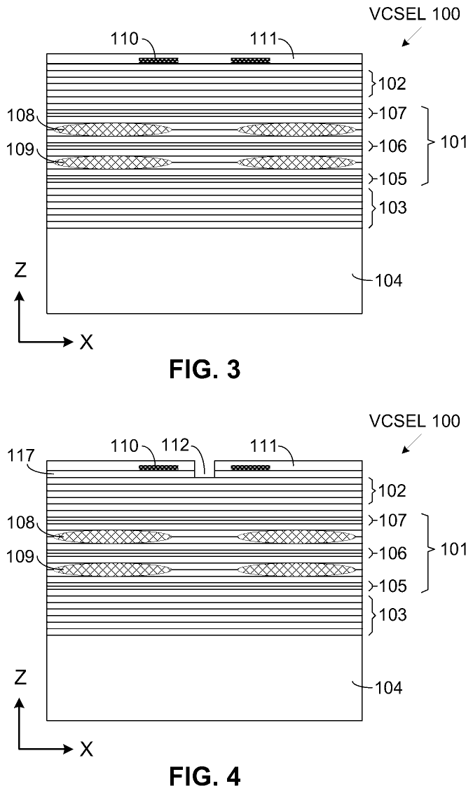

Further, a metal deposition process is performed to form a metal layer 110 over top reflector region 102. For example, a photoresist layer may be deposited over VCSEL 100. A part of the photoresist layer may be exposed and developed. Other parts of the photoresist layer that are not exposed and developed may be removed. Then, metal layer 110 may be deposited in areas where the photoresist layer is removed in a lift-off process. Metal layer 110 may have a ring shape in an X-Y plane in some cases, and is the p-metal contact that is electrically connected to top reflector region 102. The area surrounded by metal layer 110 may be referred to as the output window of VCSEL 100. A dielectric material (e.g., silicon nitride) may be deposited to form a dielectric layer 111 over metal layer 110, as shown in FIG. 3. Layer 111 is a sacrificial layer that covers and protects metal layer 110 during certain upcoming fabrication processes. Metal layer 110 and layer 111 may be deposited by chemical vapor deposition (CVD).

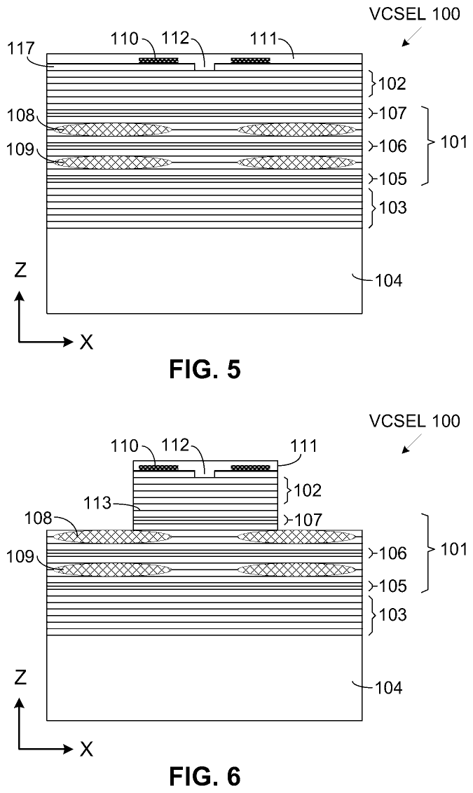

FIGS. 4 and 5 schematically show VCSEL 100 in cross-sectional views after a surface relief structure is formed according to embodiments of the present invention. A part of the layer 111 may be removed by a dry etch or a combination of dry and wet etch processes. The etch exposes an upper layer 117 formed over top reflector region 102. The exposed portion of upper layer 117 is subsequently etched away by a dry etch or dry and wet etch processes. As shown in FIG. 4, a recess 112 is formed above top reflector region 102.

Optionally, recess 112 has a circular shape within the concentric output window. The surface relief structure includes recess 112 and the remaining upper layer 117. The upper layer 117 is a quarter-wavelength layer. The term “quarter-wavelength layer” as used herein indicates a layer that has thickness of ((2n−1)/4)λ for the light in the layer, where n is an integer and λ is the wavelength. The quarter-wavelength upper layer 117 is used to construct the surface relief structure that creates a spatial variation of the cavity loss. For example, the higher-order transverse modes of the output beam are suppressed, while the centrally located fundamental LP₀₁ mode is enhanced. As such, the divergence of the output beam becomes narrower.

After recess 112 is made, the opening and recess is filled by a dielectric material such as silicon nitride temporarily, which is shown in FIG. 5. CVD may be used to deposit the dielectric material.

FIG. 6 schematically shows VCSEL 100 in a cross-sectional view after an etch process according to embodiments of the present invention. The etch process may include dry etch or a combination of dry etch and wet etch. A mesa is formed after certain parts of the top reflector region 102 and active region 107 are removed by the etch. In some other cases, the etch depth may be deeper and certain portions of active region 106 may be etched away. The mesa may optionally have a cylindrical shape and the cross-section of the mesa is a circle in an X-Y plane or horizontal plane. After the etch process, the side of a layer 113 is exposed. Layer 113 is a high Al-content layer with relatively higher aluminum content than other layers of top reflector region 102 and layers of the active regions. Layer 113 may be between top reflector region 102 and active region 107. Layer 113 may also be part of top reflector region 102 and adjacent to active region 107.

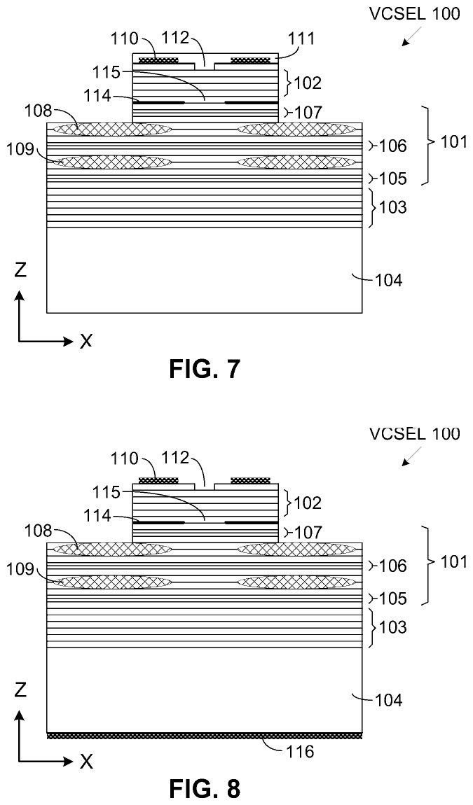

FIG. 7 schematically shows VCSEL 100 at a fabrication stage after a timed oxidation process according to embodiments of the present invention. The oxidation process may be performed in a high temperature (e.g., 400 degrees Celsius) steam environment or a dry oxygen environment. Part of high Al-content layer 113 is converted into an oxide layer 114 (e.g., AlₓO_{y} layer) by the oxidation. The oxidation rate is strongly dependent on the Al content. The part of layer 113 that is not oxidized forms an oxide aperture 115, providing electrical and optical confinement for VCSEL 100. Recess 112, the output window, oxide aperture 115, and the areas surrounded by ion implantation regions 108 and 109 are aligned along the Z direction.

Thereafter, a metal layer 116 is deposited on the bottom surface of substrate 104. Metal layers 110 and 116 serve as the anode and cathode contacts of VCSEL 100, respectively. Further, a selective etch such as a selective wet etch is performed to remove sacrificial layer 111. Metal layer 110 and recess 112 become exposed, as shown in FIG. 8.

VCSEL 100 represents a top-emitting VCSEL device or a top-emitting VCSEL structure which emits an output beam through the output window on the top surface when charged with an electrical current. In some aspects, ion implantation regions 108 and 109 have similar dimensions, and recess 112 has a smaller diameter than that of oxide aperture 115.

As illustrated above, the surface relief structure is made above top reflector region 102 and has a mechanism to suppress higher-order transverse modes of the output beam, which narrows the beam's divergent angle. Ion implantation regions 108 and 109 are used for electrical confinement, and oxide aperture 115 is used for electrical and optical confinement. If ion implantation regions 108 and 109 are replaced by additional oxide apertures, the guiding mechanism of the oxide apertures may enhance the higher-order transverse modes and increase the divergence. In addition, oxide layer 114 may have a porous structure and certain mechanical stress may be built up when oxide layer 114 is formed. The porous structure and mechanical stress may increase reliability risks. Thus, when more oxide layers are created, the reliability issues become more challenging. By combining the multi-junction active region, surface relief structure, oxide aperture, and ion implantation regions, VCSEL 100 may generate high power, reduce the divergence, and improve the yield and reliability.

In some embodiments, positions of oxide aperture 115 and ion implantation region 108 (or 109) may be switched. For example, oxide aperture 115 may be above and adjacent to active region 106, while ion implantation region 108 may be above and adjacent to active region 107.

In some cases, VCSEL 100 may have additional active regions besides active regions 105-107. In these cases, additional ion implantation regions may be formed above each added active region for electrical confinement. Alternatively, additional ion implantation region or oxide aperture may be formed above each added active region. With additional active regions and confinement structures, the VCSEL may have a higher power with similar merits to those illustrated above.

When VCSEL 100 has two active regions, an oxide aperture may be configured over one active region, an ion implantation region may be formed over the other active region, and a surface relief structure similar to that shown in FIG. 8 may be made over the top reflector region. The VCSEL may have high power, low divergence, and improved yield and reliability.

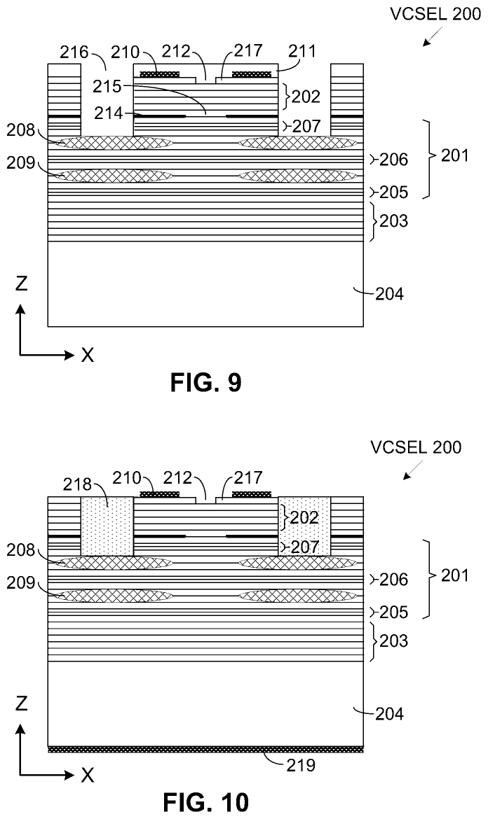

FIG. 9 schematically shows a low-divergence multi-junction VCSEL 200 in a cross-sectional view at a stage of a fabrication process according to embodiments of the present invention. VCSEL 200 may include a bottom reflector region 203 over a substrate 204, a multi-junction active region 201 over bottom reflector region 203, a top reflector region 202 over multi-junction active region 201. Top reflector region 202 may contain a p-type DBR structure, while bottom reflector region 203 may contain an n-type DBR structure. Substrate 204 may include a conductive n-type semiconductor substrate.

In some aspects, multi-junction active region 201 contains quantum-well active regions 205, 206, and 207. A tunnel junction (not shown) may be formed between adjacent active regions (e.g., between active regions 205 and 206). In some embodiments, VCSEL 200 may have two quantum-well active regions. In some other embodiments, VCSEL 200 may have more three quantum-well active regions. For example, VCSEL 200 may have a stack with additional active regions besides active regions 205-207 between the top and bottom reflector regions. The layers of the DBRs, active regions, and tunnel junctions may be grown epitaxially by MBE or MOCVD.

A trench 216 is made by etch such as a dry etch. Trench 216 may extend through top reflector region 202 and active region 207 in the Z direction, have an annular shape in an X-Y plane, and surround a cylindrical mesa. The side of a high-Al content layer (not shown) from the mesa is exposed in the trench. The high-AL content layer is disposed adjacent to and above active region 207, and beneath top reflector region 202. The high-Al content layer is oxidized in a timed oxidation process (e.g., a wet oxidation process). The oxidation process creates an oxide layer 214 with a ring shape and oxide aperture 215 with a circular shape. The ring and circle are concentric.

A metal layer 210 is deposited over an upper layer 217 before trench 216 is etched. Upper layer 217 is a quarter-wavelength layer and formed over top reflector region 202. A central part of layer 217 on the mesa is removed by etch to create a recess 212. Recess 212 and the remaining part of layer 217 on the mesa form a surface relief structure. The surface relief structure is configured to suppress higher-order transverse modes of the output beam and enhance the fundamental transverse mode. Metal layer 210 and recess 212 are covered by a sacrificial dielectric layer 211.

After the oxidation process, a CVD process is performed to fill trench 216 with a dielectric material 218 (e.g., silicon oxide, silicon nitride, or polyimide). A metal layer 219 is grown on the bottom surface of substrate 204. Metal layers 210 and 219 are the anode and cathode contacts of VCSEL 200, respectively. Further, sacrificial layer 211 is etched away in a selective etch such as a selective wet etch. Metal layer 210 and recess 212 are exposed, as shown in FIG. 10.

Alternatively, metal layer 210 may be grown after trench 216 is filled by dielectric material 218. Similarly, recess 212 may also be formed after trench 216 is filled. In some cases, recess 212 is made after metal layer 210 is deposited. Optionally, recess 212 may be made before metal layer 210 is deposited. VCSEL 200 has similar merits to that of VCSEL 100 for reasons illustrated above.

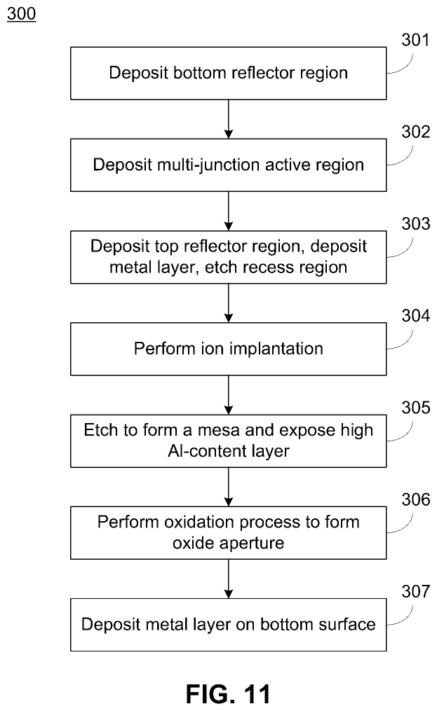

FIG. 11 is a flow chart illustrating a schematic fabrication process 300 for a low-divergence multi-junction VCSEL, according to embodiments of the present invention. Process 300 starts from providing a semiconductor substrate such as a semiconductor wafer. At step 301, multiple layers as a bottom reflector region are grown epitaxially over the substrate. The bottom reflector region includes a DBR structure. At step 302, a multi-junction active region is grown over the bottom reflector region epitaxially. The multi-junction active region may include multiple quantum-well active regions that are stacked upon each other. Each quantum-well active region contains e.g., a MQW configuration. A tunnel junction may be formed between adjacent quantum-well active regions in some cases.

At step 303, multiple layers as a top reflector region are grown over the multi-junction active region epitaxially. The top reflector region includes another DBR structure. A metal layer is deposited as the p-metal contact over the top reflector region. The metal layer forms an output window. Further, an upper layer over the top reflector region is etched to create a recess region for a surface relief structure. The upper layer is a quarter-wavelength layer. The surface relief structure facilitates lasing of the fundamental mode by limiting higher-order modes. A sacrificial dielectric layer is deposited to cover the metal layer and recess region.

At step 304, ion implantation is performed to form implantation regions. In some embodiments, multiple annular implantation regions are made with each implantation region configured above and adjacent to a quantum-well active region.

At step 305, a mesa structure is formed by etching away a part of the top reflector region. In some cases, a trench is formed by the etch. The trench encircles the mesa structure horizontally, extends through the top reflector region, and partially penetrates the quantum-well active regions along the Z direction or vertical direction. The trench exposes the side of a high Al-content layer on the sidewall of the mesa. The high Al-content layer is adjacent to and above a quantum-well active region.

At step 306, an oxidizing process (e.g., using hot water vapor) is implemented to oxidize the high Al-content layer to form an oxide layer and an oxide aperture. If a trench is made, the trench is filled with one or more dielectric materials to form an isolation region after the oxidizing process.

At step 307, a bottom contact metal layer (i.e., the n-metal contact) is deposited. The sacrificial dielectric layer is etched to expose the p-metal contact and recess region. In some other embodiments, the ion implantation process may be performed before the p-metal contact is formed, between steps 305 and 306, or between steps 306 and 307. Due to the surface relief structure, oxide aperture, and implantation regions for electrical confinement, the multi-junction VCSEL may have high power, low divergence, and improved yield and reliability. The methods illustrated above may also be used to improve the performance, yield, and reliability of VCSEL arrays. For example, VCSEL 200 as shown in FIG. 10 may be one of the VCSEL emitters of a VCSEL array.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments. Furthermore, it is intended that the appended claims cover any and all such applications, modifications, and embodiments within the scope of the present invention.

We claim:

1. A Vertical Cavity Surface Emitting Laser (VCSEL) device, comprising:
a substrate;
a first reflector region over the substrate;
a second reflector region over the first reflector region;
a plurality of active regions between the first reflector region and second reflector region;
an oxide aperture between the first reflector region and second reflector region;
an implantation region between the first reflector region and second reflector region for electrical confinement; and
a surface relief structure over the second reflector region.

2. The VCSEL device of claim 1, wherein the first reflector region and the second reflector region each comprise a Distributed Bragg Reflector (DBR) structure.

3. The VCSEL device of claim 1, wherein the plurality of active regions each include a quantum-well configuration.

4. The VCSEL device of claim 1, wherein the oxide aperture is between the second reflector region and the plurality of active regions.

5. The VCSEL device of claim 1, wherein the implantation region is between two of the plurality of active regions.

6. The VCSEL device of claim 1 further comprising another implantation region between the first reflector region and second reflector region for electrical confinement.

7. The VCSEL device of claim 1, wherein the surface relief structure has a mechanism to suppress higher-order modes of an output beam of the VCSEL device.

8. A method for fabricating a Vertical Cavity Surface Emitting Laser (VCSEL) device, comprising:
growing a first reflector region over a substrate;
growing a plurality of active regions over the first reflector region;
growing a second reflector region over the plurality of active regions;
forming an implantation region between the first reflector region and second reflector region for electrical confinement;
forming an oxide aperture between the first reflector region and second reflector region; and
forming a surface relief structure over the second reflector region.

9. The method of claim 8, wherein the first reflector region and the second reflector region each comprise a Distributed Bragg Reflector (DBR) structure.

10. The method of claim 8, wherein the plurality of active regions each include a quantum-well configuration.

11. The method of claim 8, wherein the oxide aperture is formed between the second reflector region and the plurality of active regions.

12. The method of claim 8, wherein the implantation region is between two of the plurality of active regions.

13. The method of claim 8 further comprising forming another implantation region between the first reflector region and second reflector region for electrical confinement.

14. The method of claim 8, wherein the surface relief structure has a mechanism to suppress higher-order modes of an output beam of the VCSEL device.

15. A Vertical Cavity Surface Emitting Laser (VCSEL) device, comprising:
a substrate;
a first reflector region over the substrate;
a second reflector region over the first reflector region;
a plurality of active regions between the first reflector region and second reflector region;
an oxide aperture between the first reflector region and second reflector region;
a first implantation region between the first reflector region and second reflector region;
a second implantation region between the oxide aperture and the first implantation region; and
a surface relief structure over the second reflector region.

16. The VCSEL device of claim 15, wherein the first reflector region and the second reflector region each comprise a Distributed Bragg Reflector (DBR) structure.

17. The VCSEL device of claim 15, wherein the plurality of active regions each include a quantum-well configuration.

18. The VCSEL device of claim 15, wherein the oxide aperture is between the second reflector region and the plurality of active regions.

19. The VCSEL device of claim 15, wherein the first implantation region is between two of the plurality of active regions.

20. The VCSEL device of claim 15, wherein the surface relief structure has a mechanism to suppress higher-order modes of an output beam of the VCSEL device.
